(19) United States
(12) Patent Application Publication
(10) Pub. No.: US 2010/0127375 A1
(43) Pub. Date: May 27, 2010

(54) WAFER LEVEL CHIP SCALE SEMICONDUCTOR PACKAGES

(76) Inventors: Manolito Galera, Singapore (SG); Leocadio Morona Alabin, Singapore (SG); Maria Cristina B. Estacio, Lapulapu City (PH)

Correspondence Address: KENNETH E. HORTON;KIRTON & MCCONKLE, 60 EAST SOUTH TEMPLE, SUITE 1800, SALTLAKE CITY, UT, 84111, US

(21) Appl. No.: 12/276,074

(22) Filed: Nov. 21, 2008

(51) Int. Cl. H01L 23/48; H01L 21/82

(52) U.S. Cl. 257/690; 438/113; 257/E21.602; 257/E23.011

(57) ABSTRACT

Wafer-level chip scale (WLCSP) semiconductor packages and methods for making and using the same are described. The WLCSP semiconductor packages contain a grid array of land pads rather than solder balls or solder bumps. The land pads can be provided directly on a semiconductor wafer by using a leadframe interconnect structure that has been formed from a leadframe. The land pads can be used to mount the WLCSP to a circuit board. Such a configuration allows the formation of a thinner chip scale semiconductor package using a simpler manufacturing process, thereby reducing costs and improving performance. Other embodiments are described.

### FIELD

This application relates generally to semiconductor devices and methods for making such devices. More specifically, this application describes wafer-level chip scale semiconductor packages and methods for making and using such packages.

### BACKGROUND

Semiconductor packages are well known in the art. Often, these packages may include one or more semiconductor devices, such as an integrated circuit (“IC”) die or chip, which may be connected to a die pad that is centrally formed in a lead frame which contain a series of leads. In some cases, bond wires electrically connect the IC die to a series of terminals that serve as an electrical connection to an external device, such as a printed circuit board (“PCB”). An encapsulating material can be used to cover the bond wires, the IC die, the terminals, and/or other components of the semiconductor device to form the exterior of the semiconductor package. A portion of the terminals and possibly a portion of the die pad may be externally exposed from the encapsulating material. In this manner, the die may be protected from environmental hazards—such as moisture, contaminants, corrosion, and mechanical shock—while being electrically and mechanically connected to an intended device that is external to the semiconductor package.

After it has been formed, the semiconductor package is often used in an ever growing variety of electronic applications, such as disk drives, USB controllers, portable computer devices, cellular phones, and so forth. Depending on the die and the electronic application, the semiconductor package may be highly miniaturized and may need to be as small as possible.

### SUMMARY

This application relates to wafer-level chip scale (WLCSP) semiconductor packages and methods for making and using the same. The WLCSP semiconductor packages contain a grid array of land pads rather than solder balls or solder bumps. The land pads can be provided directly on a semiconductor wafer by using a leadframe interconnect structure that has been formed from a leadframe. The land pads can be used to mount the WLCSP to a circuit board. Such a configuration allows the formation of a thinner chip scale semiconductor package using a simpler manufacturing process, thereby reducing costs and improving performance.

### BRIEF DESCRIPTION OF THE DRAWINGS

The following description can be better understood in light of the Figures, in which:

FIG. 1 shows some embodiments of a method for making semiconductor packages containing a wafer with bond pads;

FIG. 2 depicts some embodiments of a method for making semiconductor packages containing solder paste on the bond pads;

FIG. 3 shows some embodiments of a method for making semiconductor packages containing a leadframe interconnect structure;

FIG. 4 depicts some embodiments of a method for making semiconductor packages containing a leadframe interconnect structure located on a wafer with bond pads;

FIG. 5 shows some embodiments of a method for making semiconductor packages containing the structure of FIG. 4 with molding;

FIG. 6 shows some embodiments of a method for making semiconductor packages containing the structure of FIG. 5 with molding;

FIG. 7 shows some embodiments of a method for making semiconductor packages containing a wafer with bond pads;

FIG. 8 shows some embodiments of a method for making semiconductor packages containing a redistribution leadframe interconnect structure;

FIGS. 9-10 depict some embodiments of a method for making semiconductor packages containing a redistribution leadframe interconnect structure located on a wafer with bond pads;

FIG. 11 shows some embodiments of a method for making semiconductor packages containing the structure of FIGS. 9-10 with molding;

FIG. 12 shows some embodiments of a method for making semiconductor packages containing a wafer;

FIG. 13 depicts some embodiments of a method for making semiconductor packages containing a wafer with bond pads;

FIGS. 14-18 show some embodiments of a method for making a molded leadframe structure;

FIG. 19 depicts some embodiments of a method for making semiconductor packages containing a molded leadframe structure located on a wafer;

FIG. 20 depicts some embodiments of a method for making semiconductor packages containing a molded leadframe structure located on a wafer that has been reflowed;

FIG. 21 depicts some embodiments of a method for making semiconductor packages containing a molded leadframe structure located on a wafer that has been sawed;

FIG. 22 depicts some embodiments of a WLCSP; and

FIG. 23 depicts some embodiments of a WLCSP attached to a circuit board

The Figures illustrate specific aspects of the semiconductor packages and methods for making such devices. Together with the following description, the Figures demonstrate and explain the principles of the methods and structures produced through these methods. In the drawings, the thickness of layers and regions are exaggerated for clarity. It will also be understood that when a layer, component, or substrate is referred to as being “on” another layer, component, or substrate, it can be directly on the other layer, component, or substrate, or intervening layers may also be present. The same reference numerals in different drawings represent the same element, and thus their descriptions will not be repeated.

### DETAILED DESCRIPTION

The following description supplies specific details in order to provide a thorough understanding. Nevertheless, the skilled artisan would understand that the semiconductor packages and associated methods of using the packages can be implemented and used without employing these specific details. Indeed, the semiconductor packages and associated methods can be placed into practice by modifying the illustrated devices and methods and can be used in conjunction with any other apparatus and techniques conventionally used in the industry. For example, while the description below focuses on methods for making for semiconductor packages in the IC industry, it could be used for packaging for other electronic devices like optoelectronic devices, solar cells, MEMS structures, lighting controls, power supplies, and amplifiers.

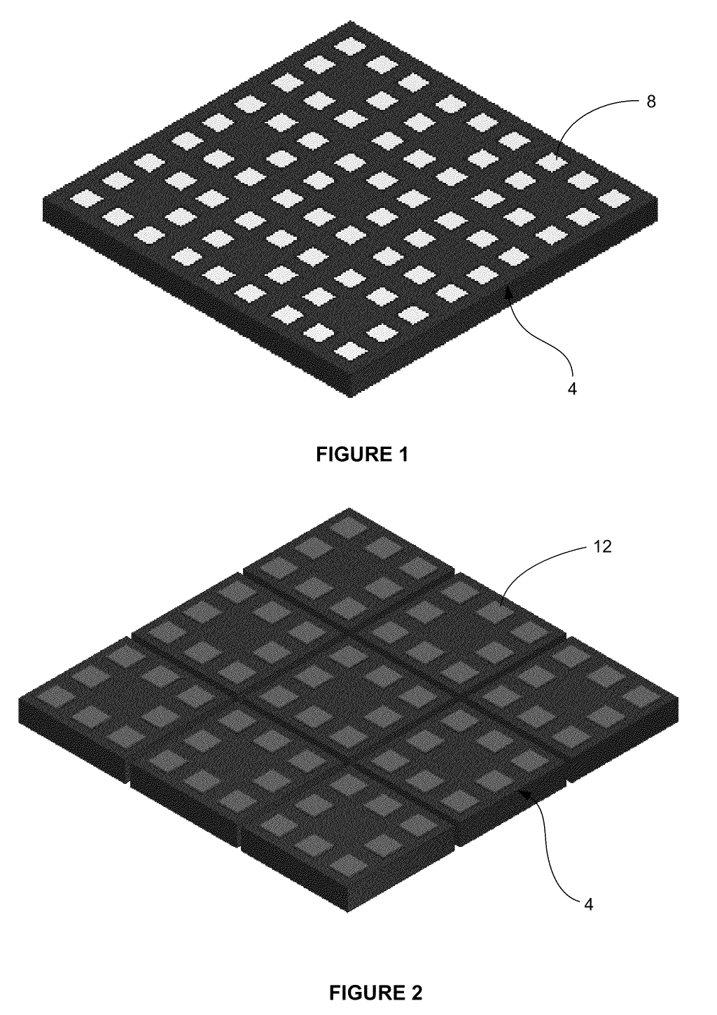

Some embodiments of the semiconductor packages and methods for making and using such packages are shown in FIGS. 1-11. In these embodiments, the methods for making the semiconductor packages can begin by providing a semiconductor wafer (or substrate) 4 that contains any number and combination of integrated circuits and/or discrete devices (not shown). The wafer 4 may be made of any suitable semiconductor material. Some non-limiting examples of such materials may include silicon, gallium arsenide, silicon carbide, gallium nitride, silicon and germanium, and the like.

In some embodiments, the wafer 4 can contain any number of IC devices known in the art. Some non-limiting examples of the IC devices include audio amplifier, LDO, logic driver, signal switch, or combinations thereof. In other embodiments, the wafer 4 can contain any number of discrete devices. Any discrete device known in the art can be used, including diodes and/or transistors. Examples of the discrete devices include zener diodes, schottky diodes, small signal diodes, bipolar junction transistors (“BJT”), metal-oxide-semiconductor field-effect transistors (“MOSFET”), insulated-gate-bipolar transistors (“IGBT”), insulated-gate field-effect transistors (“IGFET”), or combinations thereof.

The semiconductor wafer 4 can then be provided with an array of bond pads 8 over the desired locations of the wafer 4, as shown in FIG. 1. The bond pads 8 are provided in those areas to overlay the IC/discrete devices and in those areas in which the interconnect leadframe structure will later be provided. The bond pads 8 can be formed in the desired location by any process known in the art, including any method of deposition such as chemical vapor deposition (CVD), low-pressure VCD (LPCVD), plasma assisted CVD (PECVD), sputter deposition, or combinations thereof. The bond pads 8 can be made of any known solderable material, including Sn, Ag, Ti, W, Au, Cu and Ni or combinations thereof.

As shown in FIG. 2, a solder paste 12 can then be provided on the bond pads 8. The solder paste 12 can be made of any solderable adhesive material, including Ag, Sn, Pb, Cu and Sb or combinations thereof. The solder paste 12 can be provided on the bond pads through any process known in the art, including dispensing or any screen printing process.

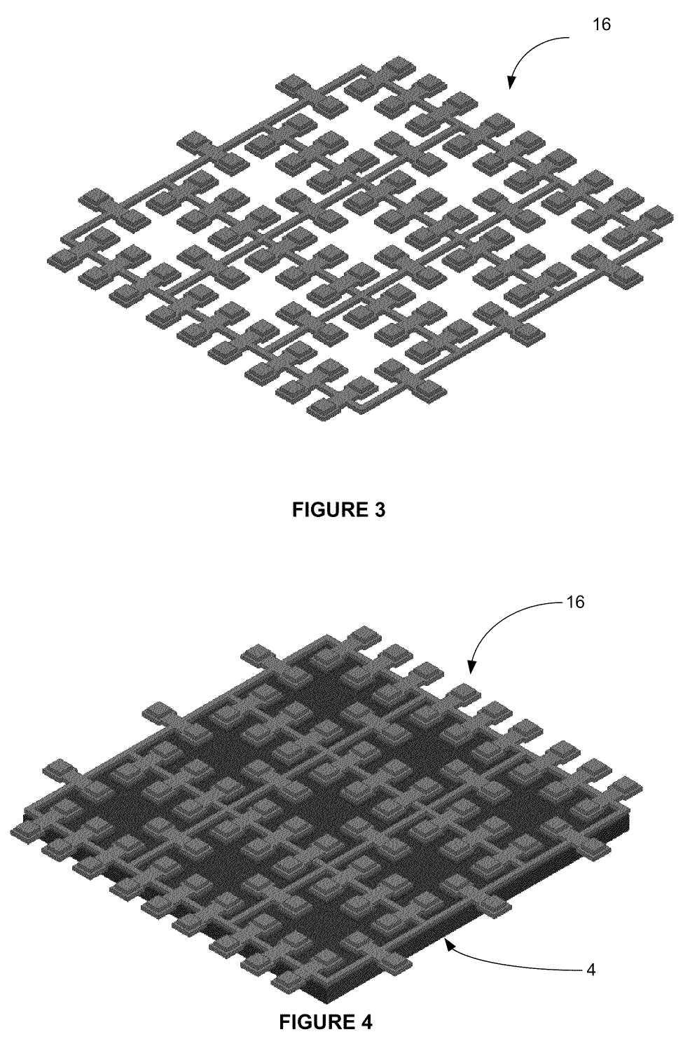

Next, a leadframe interconnect structure 16 can be provided, as shown in FIG. 3. This structure can actually be provided before the wafer 4 is provided and/or before the bond pads 8 are provided on the wafer 4. The leadframe interconnect structure 16 can be made from any lead frame known in the art and is configured according to the bond pad layout and the desired footprint of the final semiconductor package, as well as the bond pad layout. The leadframe interconnect structure 16 can comprise any conductive metal or metal alloy known in the art, including Cu, Ni—Pd, Ni—Pd—Au, Ni—Pd—Au/Ag, Ni—Fe or combinations thereof. The leadframe interconnect structure 16 can be manufactured by any known process, such as a stamping or a high-accuracy etching process such as those use in stencil fabrication.

Next, as shown in FIG. 4, the leadframe interconnect structure 16 can be attached to the bond pads 8 using any process known in the art. In this process, the material of the leadframe interconnect structure 16 connects to the bond pads 8 via the solder paste 12. In some embodiments, the alignment between the leadframe interconnect structure 16 can be controlled during this process by using a pick & place system with high precision controlled x-y table and pattern recognition system (PRS) capability. Then, a reflow process is performed to reflow the solder paste 12. Any reflow process known in the art can be used.

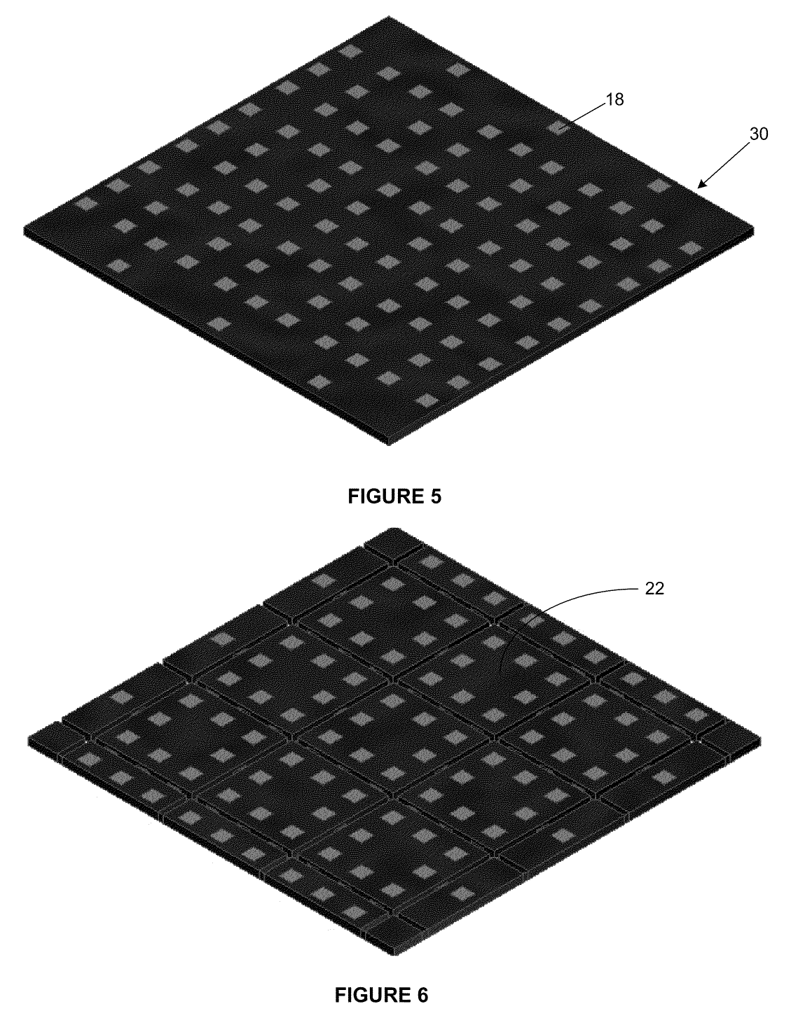

The resulting structure can then be encapsulated in any molding material 30 known in the art, as shown in FIG. 5. In some embodiments, the molding material 30 can comprise an epoxy molding compound, a thermoset resin, a thermoplastic material, or potting material. In other embodiments, the molding material can comprise an epoxy molding compound. The molding material 30 may be formed using any encapsulation process known in the art, including that described in U.S. Pat. No. 6,346,433 or any low compression molding process using a resin powder designed for compression-type molding.

As depicted in FIG. 5, the molding material 30 does not encapsulate the upper surface of the leadframe interconnect structure 16. Thus, the exposed surfaces form an array of land pads or lands 18. The lands 18 can have any configuration known in the art consistent with their operation in the semiconductor package. Thus, in the illustrated embodiments, the lands 18 are given a substantially rectangular configuration with a size of about 0.0625 mm². In other embodiments, though, the lands 18 can have a round or other suitable geometrical shape in application and a size ranging from about 0.04 mm² to about 0.25 mm².

The molded wafer structure shown in FIG. 5 is then optionally plated with Sn, electrically tested, and marked using any processes known in the art. As shown in FIG. 6, the molded wafer can then be singulated into multiple, individual WLSCPs 22. The molded wafer can be singulated using any process known in the art, including a saw singulation process or laser cutting method. The WLSCP 22 can then be taped and reeled using any process known in the art. The exposed lands 18 can then be connected to an external device, such as a PCB, using any procedure known in the art.

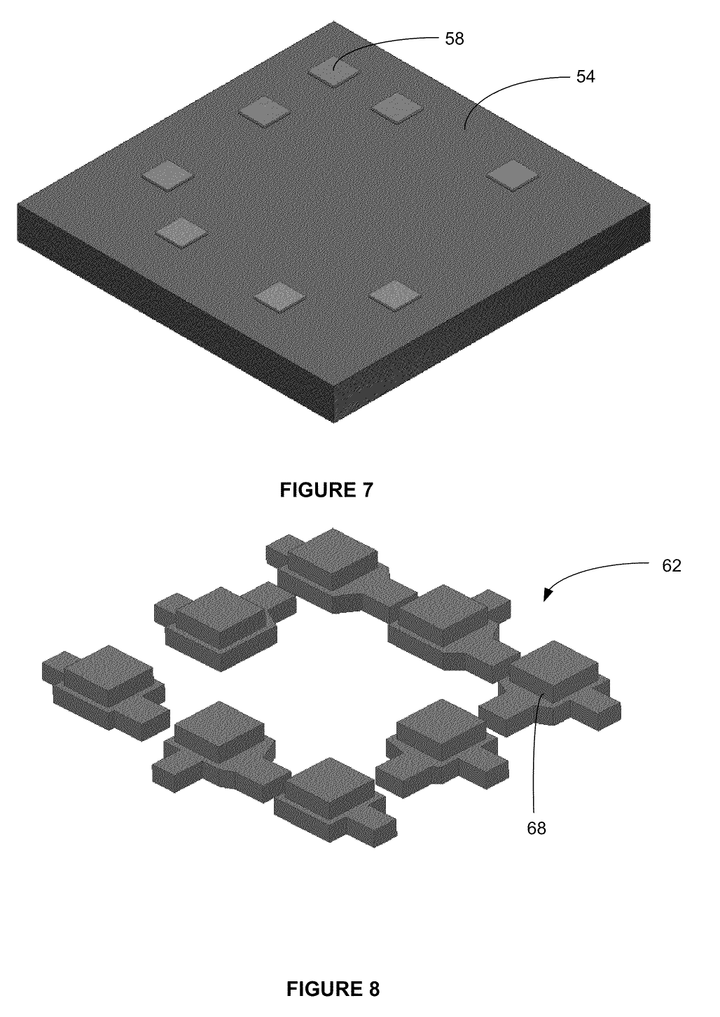

In other embodiments, the semiconductor package can be configured with a redistribution of the bond pad layout to the land pad layout. In these embodiments, as shown in FIG. 7, the die (that is part of a wafer) 54 contains a non-linear distribution of bond pads 58. Then, as shown in FIG. 8, the leadframe interconnect structure 62 that is formed contains a pattern that redistributes the bond pad layout to a more linear configuration. The lands 66 of the leadframe interconnect structure 62 contain a half etched portion 68 at the edge of the land that improves the lead locking and provides a better sawing quality. The leadframe interconnect structure 62 can be routed and customized for a wide variety of bond pad configurations, not just those illustrated in FIG. 7. This rerouting function allows the semiconductor package to be configured with many different sizes and shapes of bond pads, different sizes of wafers, and different devices contained in the wafers.

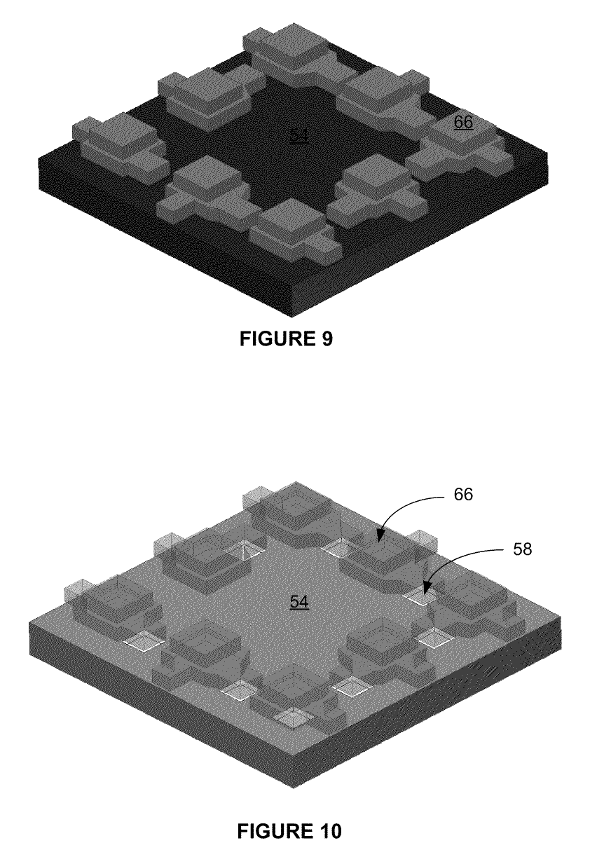

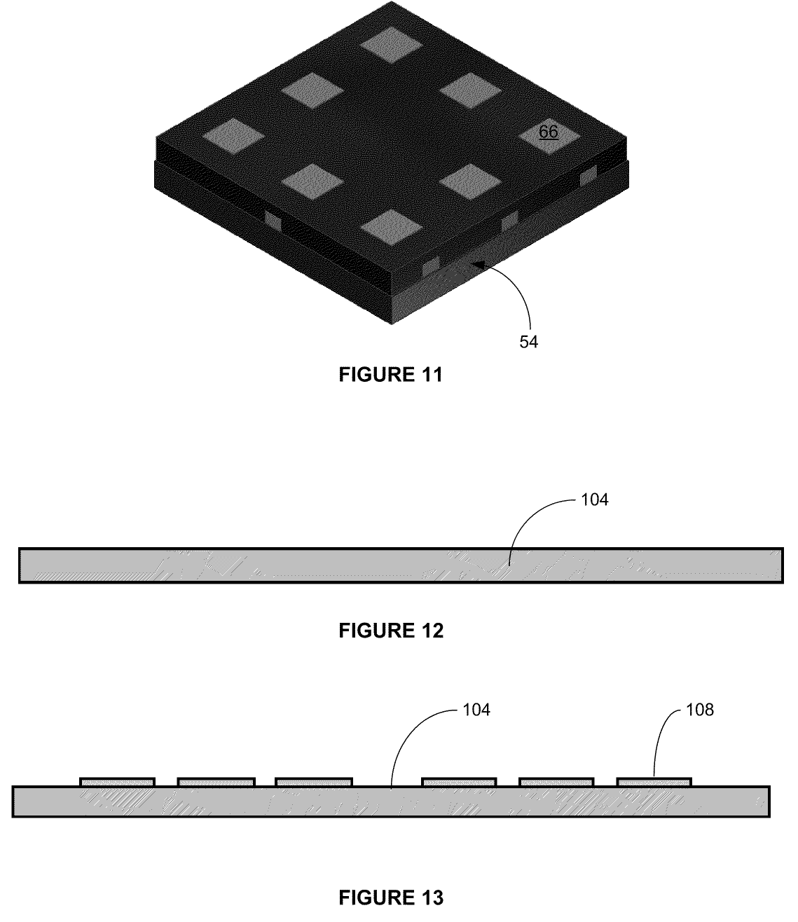

In these embodiments, the leadframe interconnect structure 62 is then attached to the die 54 as shown in FIG. 9. The resulting redistribution pattern from the bond pads 58 to the land pads or lands 66 can be seen in FIG. 10. Next, the wafer containing the die 54 is then molded in a molding material 72, optionally plated, electrically tested, marked, singulated, and taped & reeled to manufacture a WLSCP 80, as shown in FIG. 11. The lands 66 that remain exposed can be connected to an external device, such as a PCB, using any procedure known in the art.

The WLCSP 80 that is manufactured contains a substantially flat array of land pads. When compared to solder balls that are typically used in WLCSP, this feature is more robust in terms of both mechanical stress and board mounting stress. As well, this feature provides a better test contact and flexibility for the pins and probes (like cantilever type contact fingers or spring loaded test pins) used to test the WLCSP because of the flat land surface of the package.

The methods described above also provide several features to the WLCSP. First, they allow the WLCSP to be able to be mounted to a PCB without the need for any underfill, thereby significantly reducing the board space requirement of the PCB and reducing the cost of mounting the WLCSP to the PCB. Another feature is that by using the array of flat lands, the WLCSP can be manufactured thinner than those that use solder balls or bumps. Another feature is that the methods form a WLCSP with a lower manufacturing cost and uses fewer processing flows, yet still is able to use conventional assembly processes. Another feature is that when compared to near-CSP packages such as quad, flat no-lead (QFN) semiconductor packages, the WLSCPs described herein do not require die attach processes nor any wirebonding. Finally, the methods provide a board mount chip scale package (CSP) that is reworkable since the mounting rework can be done just like conventional surface mount packages such as QFN.

In still other embodiments, the WLCSPs can be formed in a different process that is depicted in FIGS. 12-23. As shown in FIG. 12, this process begins by providing a semiconductor wafer (or substrate) 104 that contains any number of integrated circuits and/or discrete devices. The wafer 104 may be made of any suitable semiconductor material, including silicon, gallium arsenide, silicon carbide, gallium nitride, silicon and germanium, and the like. The wafer 104 can contain any number of IC or discrete devices known in the art, including any of those described herein.

As shown in FIG. 13, the semiconductor wafer 104 can then be provided with an array of bond pads 108 over the desired locations of the wafer 104. The bond pads 108 are provided to overlay the array of IC/discrete device and in those areas which in which the molded leadframe interconnect structure will later be provided. The bond pads 108 can be formed in the desired location by any process known in the art. The bond pads 108 can be made of any known solderable material, including Cu, Ag, Ni, Au, or electroless nickel-gold (ENIG) plating.

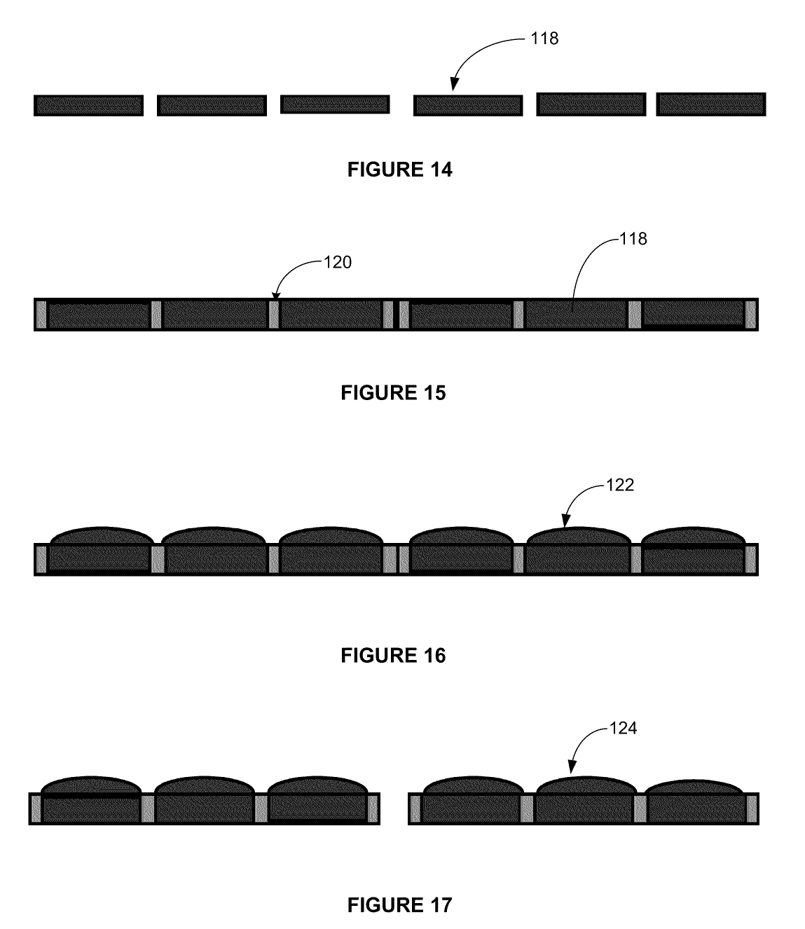

Next, a molded leadframe interconnect structure can be provided using the process depicted in FIGS. 14-18. The molded leadframe interconnect structure can actually be provided before the wafer 104 is provided and/or before the bond pads 108 are provided on the wafer. The process begins by providing any leadframe 118 known in the art, as shown in FIG. 14. The leadframe 118 can comprise any conductive metal or metal alloy known in the art, including Cu, Ni, Ni—Pd, Ni—Pd—Au, Ni—Pd—Au/Ag, or combinations thereof. In some embodiments, the leadframe 118 comprises Cu with or without a Ni Ni—Pd—Au plating. The leadframe 118 can be manufactured by any known process, such as a stamping or etching process.

As shown in FIG. 15, a molding material 120 is then provided around the leadframe 118. In some embodiments, the molding material 120 can comprise an epoxy molding compound, a thermoset resin, a thermoplastic material, or potting material. In other embodiments, the molding material comprises an epoxy molding compound. The molding material 120 may be formed using any encapsulation process known in the art, including transfer molding.

As depicted in FIG. 15, the molding material 120 does not encapsulate the upper surface and lower surfaces of the leadframe 118, thereby leaving them exposed. Next, as shown in FIG. 16, small solder bumps 122 are formed on the exposed upper surface of the leadframe 118 using any known process. In some embodiments, the small solder bumps 122 are formed by screen printing any known solder paste and then performing a reflow process.

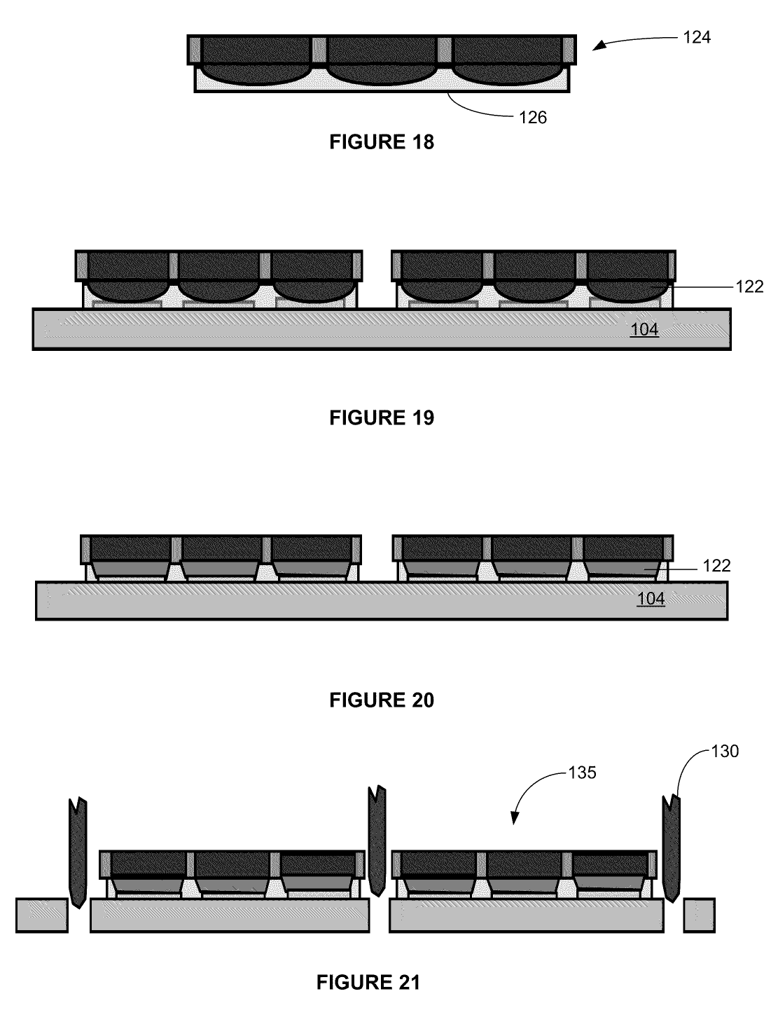

As shown in FIG. 17, the structure in FIG. 16 can be singulated to create molded leadframe interconnect frames (or molded frames) 124. The singulation can be carried out using any singulation process known in the art, including saw singulation. The molded fames 124 are then attached to bond pads 108 on the wafer 104 using any process known in the art. In some embodiments, the orientation of the molded frames 124 can be controlled by using a pick & place method that picks up the molded frames 124. During this process, the molded frames 124 are flipped and dipped in a flux material so that a flux underfill 126 is created on the small solder bumps 122, as shown in FIG. 18. Alternatively, the flux material could be placed on the wafer 104 in the desired areas where the molded frames will be placed. Once the molded frames 124 have been placed in the desired location over the bond pads 108 (as shown in FIG. 19), a reflow process is performed so that the small solder bumps 122 are reflowed as shown in FIG. 20.

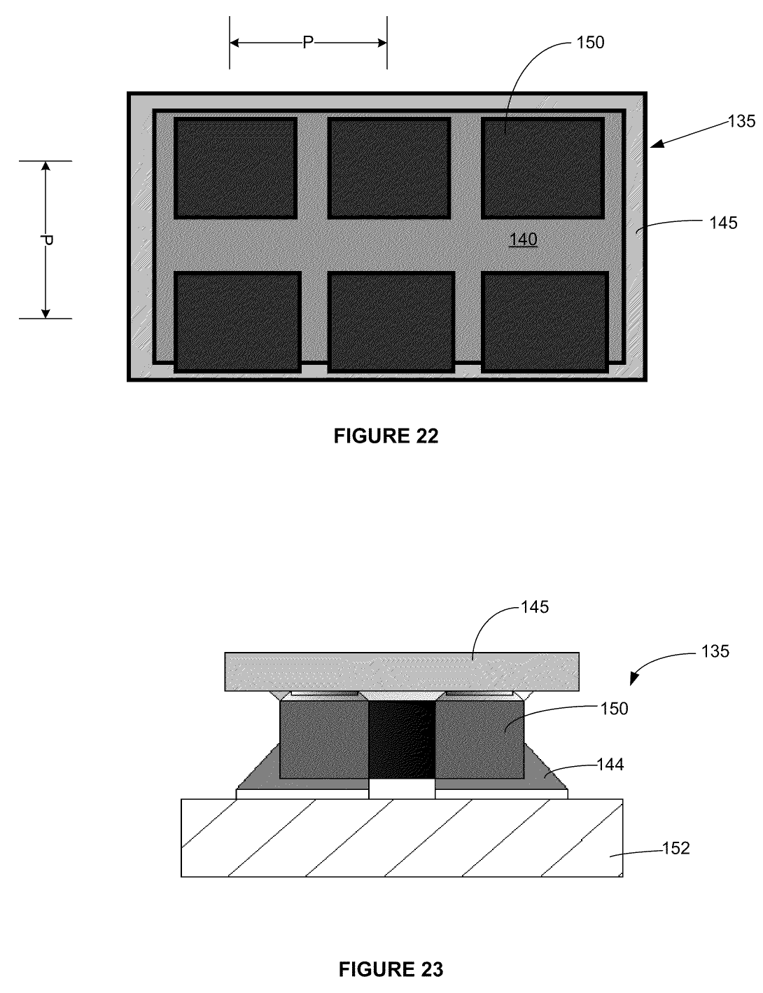

As shown in FIG. 21, the resulting structure can be singulated into multiple, individual WLSCPs. The singulation can be carried out using any process known in the art, including a saw singulation process using a saw 130. The WLSCPs 135, as shown in FIG. 22, can then be taped and reeled using any process known in the art. The molded area 140 of the WLCSP 122 is smaller than the area of the underling die 145. The pitch P of the WLCSP 122 can range from about 0.30 mm and above. In some embodiments, the pitch can range from about 0.30 to about 0.35 mm.

With these pitches and die of about 0.1 mm, the thickness of the WLCSP can be greater than about 0.20 mm and, in some instances, can even range from about 0.20 mm to about 0.325 mm. Thus, the thickness of the non-die components in the WLCSP can range from about 0.1 mm to about 0.225 mm. And if the thickness of the die is decreased down to about 50 μm, the thickness of the WLSCP can range from about 0.15 to about 0.25 mm.

The exposed lands 150 of the WLCSP 135 can be connected using solder 144 to an external device, such as a PCB 152, using any procedure known in the art as depicted in FIG. 23. The lands 150 will accommodate a good solder fillet formation with the PCB. And the flux underfill allows an added protection on the passivation that can be used on the die 145.

The WLSCPs formed in these later embodiments also contains exposed lands and therefore do not contains solder balls. Thus, the board mount interconnection can accommodate a pitch ranging from about 0.30 mm to about 0.35 mm. Likewise, the WLCSPs have a better board-level reliability since solder balls tend to have a higher probably of failure due to solder cracking. The flux underfill in the WLCSPs provides a mechanical stability to the interconnect that can withstand board mounting processes and rework procedures. The board mount interconnection also allows fillet formation along the dies of the lands that improves the solder joint reliability. And the die surface in the WLCSP is protected by the molded frames which reduces or eliminates surface damage to the die and the die will have a better mechanical stability down to die sizes of about 50 μm.

In addition to any previously indicated modification, numerous other variations and alternative arrangements may be devised by those skilled in the art without departing from the spirit and scope of this description, and appended claims are intended to cover such modifications and arrangements. Thus, while the information has been described above with particularity and detail in connection with what is presently deemed to be the most practical and preferred aspects, it will be apparent to those of ordinary skill in the art that numerous modifications, including, but not limited to, form, function, manner of operation and use may be made without departing from the principles and concepts set forth herein. Also, as used herein, examples are meant to be illustrative only and should not be construed to be limiting in any manner.

1. A wafer level chip scale semiconductor package, comprising:
a die on first side of the semiconductor package, the die containing a first array of integrated circuit devices, discrete devices, or a combination thereof;
a bond pad array disposed on the first array;
an array of land pads on a second side of the semiconductor package which is opposite the first, the land pad array being formed from a leadframe interconnect structure; and
a molding material encapsulating the die, the bond pads, and the array of land pads except for an upper surface of the land pads.

2. The semiconductor package of claim 1, wherein the array of land pads comprise terminals for the package to connect to a printed circuit board.

3. The semiconductor package of claim 2, wherein the connection to the printed circuit board does not contain a solder ball or solder bump.

4. The semiconductor package of claim 1, wherein the design of the leadframe interconnect structure is substantially similar to the layout of the land pad array.

5. The semiconductor package of claim 4, wherein the leadframe interconnect structure redistributes the layout of bond pad array.

6. The semiconductor package of claim 1, wherein the land pads comprise a half-etch edge.

7. The semiconductor package of claim 1, wherein the pitch of the land pad array ranges from about 0.30 mm to about 0.35 mm.

8. The semiconductor package of claim 1, wherein the thickness of the non-die components of the semiconductor package ranges from about 0.1 mm to about 0.225 mm.

9. A method for making a wafer level chip scale semiconductor package, comprising:
providing a die on first side of the semiconductor package, the die containing a first array of integrated circuit devices, discrete devices, or a combination thereof;
providing a bond pad array disposed on the first array;
providing an array of land pads on a second side of the semiconductor package which is opposite the first, the land pad array being formed from a leadframe interconnect structure; and
providing a molding material encapsulating the die, the bond pads, and the array of land pads except for an upper surface of the land pads.

10. The method of claim 9, wherein the array of land pads comprise terminals for the package to connect to a printed circuit board.

11. The method of claim 9, wherein the connection to the printed circuit board does not contain a solder ball or solder bump.

12. The method of claim 9, wherein the design of the leadframe interconnect structure is substantially similar to the layout of the land pad array.

13. A method for making a wafer level chip scale semiconductor package, comprising:
providing a semiconductor wafer with a first array of integrated circuit devices, discrete devices, or a combination thereof;
forming a bond pad array on the first array;
forming a leadframe interconnect structure;
attaching the leadframe interconnect structure to the bond pad array to form a land pad array;
encapsulating a molding material around the die, the bond pads, and the array of land pads except for an upper surface of the land pads; and
singulating the wafer into a plurality of dies.

14. The method of claim 13, including providing a solderable material on the array of bond pads before attaching the leadframe interconnect structure.

15. The method of claim 13, including forming the leadframe interconnect structure by high accuracy etching of a leadframe.

16. The method of claim 13, including attaching the leadframe interconnect structure by a pick and place method.

17. The method of claim 13, wherein the leadframe interconnect structure redistributes the layout of bond pad array.

18. The method of claim 13, wherein the land pads comprise a half-etch edge.

19. A method for making a wafer level chip scale semiconductor package, comprising:
providing a semiconductor wafer with a first array of integrated circuit devices, discrete devices, or a combination therefo;
forming a bond pad array on the first array;
forming a leadframe interconnect structure;
encapsulating the leadframe interconnect structure to leave the upper surface exposed;
forming solder bumps on the exposed upper surfaces of the leadframe interconnect structure;
singulating the leadframe interconnect structure to form a molded frame;
attaching the molded frame to a portion of the bond pad array to form a land pad array; and
singulating the wafer into a plurality of dies.

20. The method of claim 19, including reflowing the solder bumps after the molded frame is attached to bond pad array.

21. The method of claim 19, including forming the solder bumps by screen printing a solder paste and then reflowing.

22. The method of claim 19, including attaching the molded frame by using a pick and place process.

23. The method of claim 22, wherein the pick and place process dips the solder bumps of the molded frame in a flux material before placing on the wafer.

24. The method of claim 19, wherein the wherein the pitch of the land pad array ranges from about 0.30 mm to about 0.35 mm.

25. The method of claim 19, wherein the thickness of the non-die components of the semiconductor package ranges from about 0.1 mm to about 0.225 mm.
